(19) United States
(12) Patent Application Publication
(10) Pub. No.: US 2020/0328520 A1
(43) Pub. Date: Oct. 15, 2020

(54) Antenna and Electronic Device

(71) Applicant: HUAWEI TECHNOLOGIES CO., LTD., Shenzhen, Guangdong (CN)

(72) Inventor: Shaogang DENG, Shenzhen (CN)

(21) Appl. No.: 16/305,665

(22) PCT Filed: May 31, 2016
(86) PCT No.: PCT/CN2016/084177

§ 371 Date: Nov. 29, 2018

(51) Int. Cl. H01Q 9/04; H01Q 5/335; H05K 1/02

(52) U.S. Cl. CPC H01Q 9/0457; H05K 1/0243; H01Q 5/335

(57) ABSTRACT

The present disclosure provides an antenna. The antenna includes a PCB board, a matching circuit, and a feeder. The PCB board is provided with a ground plane. The ground plane is provided with an open slot. One end of the matching circuit is connected to a signal source, and the other end of the matching circuit is connected to an end of the feeder. The feeder passes across the open slot. An endpoint of the feeder is connected to one side of the open slot. The antenna further includes a capacitor C1 and an inductor L1. The capacitor C1 and the inductor L1 are located in the open slot. The capacitor C1 and the inductor L1 are connected in series. The antenna may further generate a low frequency based on an original frequency band.

### TECHNICAL FIELD

The present invention relates to the field of antenna technologies, and in particular, to an antenna and an electronic device.

### BACKGROUND

With development of science and technology, metallic materials are usually used to design a product housing, so that electronic devices such as smartphones and tablet computers can attract consumers. The metallic materials used for the product housing may affect radiation performance of an antenna.

Compared with a conventional inverted-F antenna (IFA antenna for short) or monopole antenna (English: monopole antenna), a slot antenna may effectively resist impact, on antenna performance, of a component that is made of a metallic material and that is around the antenna.

However, the slot antenna may usually generate one frequency band. For example, the slot antenna may cover WLAN (English name: Wireless Local Area Networks) bandwidth. The WLAN bandwidth may be 2.4 GHz-2.5 GHz or 5.0 GHz-5.8 GHz. How to further cover a low frequency when the slot antenna has generated one frequency band is an urgent problem to be resolved.

### SUMMARY

The present invention provides an antenna and an electronic device, and the antenna may further generate a low frequency based on an original frequency band.

According to an aspect, the present invention provides an antenna, including a PCB board, a matching circuit, and a feeder, where the PCB board is provided with a ground plane, the ground plane is provided with an open slot, one end of the matching circuit is connected to a signal source, the other end of the matching circuit is connected to an end of the feeder, the feeder passes across the open slot, and an endpoint of the feeder is connected to one side of the open slot; and the antenna further includes a capacitor C1 and an inductor L1, where the capacitor C1 and the inductor L1 are located in the open slot, the capacitor C1 and the inductor L1 are connected in series, one end of the capacitor C1 and the inductor L1 that are connected in series is connected to the other side of the open slot, and the other end of the capacitor C1 and the inductor L1 that are connected in series is connected to the one side of the open slot.

It may be learned that the capacitor C1 and the inductor L1 that are connected in series are located in the open slot, the capacitor C1 and the inductor L1 that are connected in series are connected to two sides of the open slot, and the antenna may further cover a low frequency based on an original frequency band. In addition, the antenna uses space of the open slot, and the capacitor C1 and the inductor L1 that are connected in series are added to the open slot, so as to add the low frequency without affecting a size of the antenna.

A location at which the other end of the capacitor C1 and the inductor L1 that are connected in series is connected to the one side of the open slot is different from a location at which the endpoint of the feeder is connected to the one side of the open slot.

The other side of the open slot is opposite to the one side of the open slot.

A size of the open slot is 25 mm×2 mm.

Optionally or further, a value range of a capacitance value of the capacitor C1 is 0.5 pF-1 pF, and a value range of an inductance value of the inductor L1 is 5 nH-15 nH.

The capacitance value of the capacitor C1 is 0.5 pF, and the inductance value of the inductor L1 is 9.1 nH.

Optionally or further, a width of the feeder is 0.2 mm.

Optionally or further, the antenna may generate three operating frequencies. The three operating frequencies are 2.45 GHz, 5.5 GHz, and 1.575 GHz. In this way, the antenna may operate not only on a wireless local area network (Wireless Local Area Networks, WLAN for short) frequency band, but also on a Global Positioning System (Global Positioning System, GPS for short) frequency band.

Based on the antenna in the first aspect of the present invention, the other side of the open slot is opposite to the one side of the open slot.

A size of the printed circuit board (Printed Circuit Board, PCB for short) may be 135 mm×65 mm×1.6 mm. That is, a length of the PCB board is 135 mm, a width of the PCB board is 65 mm, and a height of the PCB board is 1.6 mm.

Optionally or further, a distance between the open slot and an edge of the PCB board is greater than or equal to 30 mm.

A location at which the other end of the capacitor C1 and the inductor L1 that are connected in series is connected to the one side of the open slot is different from a location at which the endpoint of the feeder is connected to the one side of the open slot.

Optionally or further, the size of the open slot is 10 mm×2 mm.

Optionally or further, a value range of a capacitance value of the capacitor C1 is 0.5 pF-1 pF, and a value range of an inductance value of the inductor L1 is 5 nH-15 nH.

The capacitance value of the capacitor C1 is 0.5 pF, and the inductance value of the inductor L1 is 10 nH.

Optionally or further, a width of the feeder is 0.2 mm.

Further, the antenna may generate two operating frequencies. The two operating frequencies are 5.5 GHz and 2.45 GHz. In this way, the antenna may operate not only at 5.5 GHz in a wireless local area network (Wireless Local Area Networks, WLAN for short), but also at 2.45 GHz in a wireless local area network.

According to another aspect, the present invention further provides an electronic device, including an antenna, a radio frequency processor, and a baseband processor, where

the antenna includes a PCB board, a matching circuit, and a feeder, where the PCB board is provided with a ground plane, the ground plane is provided with an open slot, one end of the matching circuit is connected to a signal source, the other end of the matching circuit is connected to an end of the feeder, the feeder passes across the open slot, and an endpoint of the feeder is connected to one side of the open slot; and the antenna further includes a capacitor C1 and an inductor L1, where the capacitor C1 and the inductor L1 are located in the open slot, the capacitor C1 and the inductor L1 are connected in series, one end of the capacitor C1 and the inductor L1 that are connected in series is connected to the other side of the open slot, and the other end of the capacitor C1 and the inductor L1 that are connected in series is connected to the one side of the open slot;

the baseband processor is connected to the signal source by using the radio frequency processor; and

the antenna is configured to: transmit a received radio signal to the radio frequency processor, or convert a transmit signal of the radio frequency processor into an electromagnetic wave and send the electromagnetic wave; the radio frequency processor is configured to: perform frequency selection, amplification, and down-conversion processing on the radio signal received by the antenna, convert a processed signal into an intermediate frequency signal or a baseband signal, and send the intermediate frequency signal or the baseband signal to the baseband processor; or perform up-conversion and amplification on a baseband signal or an intermediate frequency signal sent by the baseband processor, and send a processed signal by using the antenna; and the baseband processor processes the received intermediate frequency signal or the received baseband signal.

A location at which the other end of the capacitor C1 and the inductor L1 that are connected in series is connected to the one side of the open slot is different from a location at which the endpoint of the feeder is connected to the one side of the open slot.

The other side of the open slot is opposite to the one side of the open slot.

Optionally or further, for the antenna in the first aspect and the electronic device in the another aspect, a distance between the feeder 70 and an opening of the open slot 11 may be 4 mm.

For the antenna in the first aspect and the electronic device in the another aspect, the ground plane may be a copper plane of the PCB board.

It may be learned that the capacitor C1 and the inductor L1 that are connected in series are located in the open slot, the capacitor C1 and the inductor L1 that are connected in series are connected to two sides of the open slot, and the antenna may further cover a low frequency based on an original frequency band. In addition, the antenna uses space of the open slot, and the capacitor C1 and the inductor L1 that are connected in series are added to the open slot, so as to add the low frequency without affecting a size of the antenna. Further, the antenna is used on the electronic device, so that impact of a surrounding metal component on antenna performance can be reduced.

### BRIEF DESCRIPTION OF DRAWINGS

FIG. 1 is a schematic diagram of an embodiment of an antenna according to the present invention;

FIG. 2 is a schematic diagram of an antenna return loss curve when a capacitor and an inductor that are connected in series are added to an open slot and an antenna return loss curve when no capacitor and inductor that are connected in series are added to an open slot according to Embodiment 1 of an antenna of the present invention;

FIG. 3 is a schematic diagram of a curve of a real part of impedance when a capacitor and an inductor that are connected in series are added to an open slot and a curve of a real part of impedance when no capacitor and inductor that are connected in series are added to an open slot according to Embodiment 1 of an antenna of the present invention;

FIG. 4 is a schematic diagram of current distribution when a capacitor and an inductor that are connected in series are added to an open slot according to Embodiment 1 of an antenna of the present invention;

FIG. 5 is a schematic diagram of electric field distribution when a capacitor and an inductor that are connected in series are added to an open slot according to Embodiment 1 of an antenna of the present invention;

FIG. 6 is a diagram of an antenna curve when a capacitor and an inductor that are connected in series are added to an open slot according to Embodiment 1 of an antenna of the present invention;

FIG. 7 is a schematic diagram of passive efficiency when an open slot is located at different locations on a PCB board according to Embodiment 1 of an antenna of the present invention;

FIG. 8 is a schematic diagram of a matching circuit according to Embodiment 2 of an antenna of the present invention;

FIG. 9 is a schematic diagram of an antenna return loss curve when a capacitor and an inductor that are connected in series are added to an open slot and an antenna return loss curve when no capacitor and inductor that are connected in series are added to an open slot according to Embodiment 2 of an antenna of the present invention;

FIG. 10 is a schematic diagram of a curve of a real part of impedance when a capacitor and an inductor that are connected in series are added to an open slot and a curve of a real part of impedance when no capacitor and inductor that are connected in series are added to an open slot according to Embodiment 2 of an antenna of the present invention;

FIG. 11 is a schematic diagram of current distribution when a capacitor and an inductor that are connected in series are added to an open slot according to Embodiment 2 of an antenna of the present invention;

FIG. 12 is a schematic diagram of electric field distribution when a capacitor and an inductor that are connected in series are added to an open slot according to Embodiment 2 of an antenna of the present invention;

FIG. 13 is a diagram of an antenna curve when a capacitor and an inductor that are connected in series are added to an open slot according to Embodiment 2 of an antenna of the present invention;

FIG. 14 is a schematic diagram of passive efficiency when a capacitor and an inductor that are connected in series are added to an open slot according to Embodiment 2 of an antenna of the present invention; and

FIG. 15 is a schematic diagram of Embodiment 3 of an electronic device according to the present invention.

### DESCRIPTION OF EMBODIMENTS

The following clearly describes the technical solutions in the embodiments of the present invention with reference to the accompanying drawings in the embodiments of the present invention. Apparently, the described embodiments are merely some but not all of the embodiments of the present invention. All other embodiments obtained by a person of ordinary skill in the art based on the embodiments of the present invention without creative efforts shall fall within the protection scope of the present invention.

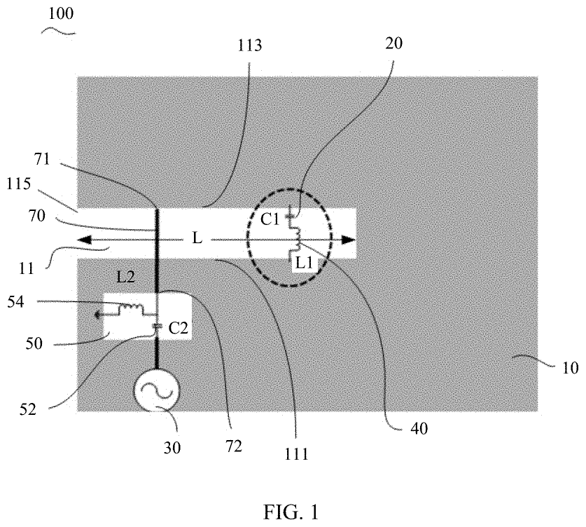

Referring to FIG. 1, FIG. 1 is a schematic diagram of an embodiment of an antenna according to the present invention. The antenna 100 includes a printed circuit board (English: Printed Circuit Board, PCB for short), a matching circuit 50, and a feeder 70. The PCB board is provided with a ground plane 10. The ground plane 10 is provided with an open slot 11. One end of the matching circuit 50 is connected to a signal source 30, and the other end of the matching circuit 50 is connected to an end 72 of the feeder 70. The feeder 70 passes across the open slot 11. An endpoint 71 of the feeder 70 is connected to one side 113 of the open slot 11. The antenna 100 further includes a capacitor C1 20 and an inductor L1 40. The capacitor C1 20 and the inductor L1 40 are located in the open slot 11. The capacitor C1 20 and the inductor L1 40 are connected in series. One end of the capacitor C1 20 and inductor L1 40 that are connected in series is connected to the other side 111 of the open slot 11. The other end of the capacitor C1 20 and inductor L1 40 that are connected in series is connected to the one side 113 of the open slot 11.

The other side 111 of the open slot 11 is opposite to the one side 113 of the open slot 11.

An opening 115 of the open slot 11 is connected to the outside. For a structure of the open slot 11, refer to the schematic diagram shown in FIG. 1. Referring to FIG. 1, the open slot 11 has two sides: the other side 111 of the open slot 11 and the one side 113 of the open slot in FIG. 1. The other side 111 and the one side 113 of the open slot 11 are rectilinear. Certainly, the structure of the open slot 11 may be alternatively another structure. For example, the other side 111 and the one side 113 of the open slot may be alternatively curvilinear.

As shown in FIG. 1, a location at which the other end of the capacitor C1 20 and the inductor L1 40 that are connected in series is connected to the one side 113 of the open slot 11 is different from a location at which the endpoint 71 of the feeder 70 is connected to the one side 113 of the open slot 11.

It may be learned from the above that the capacitor C1 20 and the inductor L1 40 that are connected in series are located in the open slot 11, the capacitor C1 20 and the inductor L1 40 that are connected in series are connected to two sides of the open slot 11, and the antenna 100 may further cover a low frequency based on an original frequency band. In addition, the antenna 100 uses space of the open slot 11, and the capacitor C1 20 and the inductor L1 40 that are connected in series are added to the open slot 11, so as to add the low frequency without affecting a size of the antenna.

### Embodiment 1

Referring to FIG. 1, FIG. 1 is a schematic diagram of an embodiment of an antenna according to the present invention. The antenna 100 includes a printed circuit board (English: Printed Circuit Board, PCB for short), a matching circuit 50, and a feeder 70. The PCB board is provided with a ground plane 10. The ground plane 10 is provided with an open slot 11. One end of the matching circuit 50 is connected to a signal source 30, and the other end of the matching circuit 50 is connected to an end 72 of the feeder 70. The feeder 70 passes across the open slot 11. An endpoint 71 of the feeder 70 is connected to one side 113 of the open slot 11. The antenna 100 further includes a capacitor C1 20 and an inductor L1 40. The capacitor C1 20 and the inductor L1 40 are located in the open slot 11. The capacitor C1 20 and the inductor L1 40 are connected in series. One end of the capacitor C1 20 and the inductor L1 40 that are connected in series is connected to the other side 111 of the open slot 11. The other end of the capacitor C1 20 and the inductor L1 40 that are connected in series is connected to the one side 113 of the open slot 11.

The other side 111 of the open slot 11 is opposite to the one side 113 of the open slot 11.

A size of the open slot 11 may be 25 mm×2 mm. That is, a length of the open slot is 25 mm, and a width of the open slot is 2 mm.

Optionally or further, a width of the feeder 70 is 0.2 mm.

Optionally or further, a distance between the feeder 70 and an opening 115 of the open slot 11 may be 4 mm.

Optionally or further, a value range of a capacitance value of the capacitor C1 20 may be 0.5 pF-1 pF, and a value range of an inductance value of the inductor L1 40 may be 5 nH-15 nH.

In this embodiment, the capacitance value of the capacitor C1 20 may be 0.5 pF, and the inductance value of the inductor L1 40 may be 9.1 nH.

Still referring to FIG. 1, the matching circuit 50 includes a capacitor C2 52 and an inductor L2 54. That one end of the matching circuit 50 is connected to a signal source 30, and the other end of the matching circuit 50 is connected to an end 72 of the feeder 70 includes: One end of the capacitor C2 52 is connected to the signal source 30, the other end of the capacitor C2 52 is connected to the feeder 70, one end of the inductor L2 54 is connected to the other end of the capacitor C2 52 and the end 72 of the feeder 70, and the other end of the inductor L2 54 is grounded. That the other end of the inductor L2 54 is grounded may be: The other end of the inductor L2 54 is connected to the ground plane 10.

As shown in FIG. 1, a location at which the other end of the capacitor C1 20 and the inductor L1 40 that are connected in series is connected to the one side 113 of the open slot 11 is different from a location at which the endpoint 71 of the feeder 70 is connected to the one side 113 of the open slot 11.

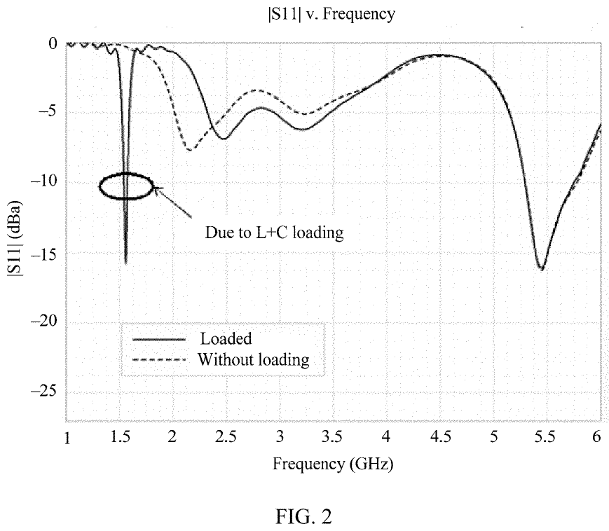

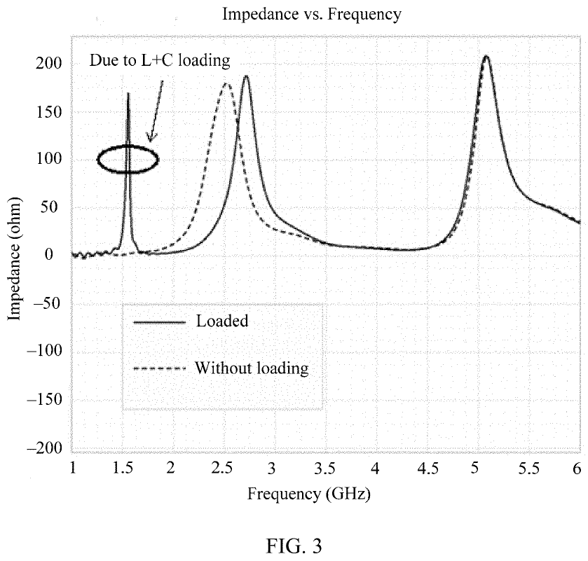

Referring to FIG. 2, FIG. 2 is a schematic diagram of an antenna return loss curve when a capacitor and an inductor that are connected in series are added to an open slot and an antenna return loss curve when no capacitor and inductor that are connected in series are added to an open slot according to Embodiment 1 of an antenna of the present invention. Referring to FIG. 3, FIG. 3 is a schematic diagram of a curve of a real part of impedance when a capacitor and an inductor that are connected in series are added to an open slot and a curve of a real part of impedance when no capacitor and inductor that are connected in series are added to an open slot according to Embodiment 1 of an antenna of the present invention.

As shown in FIG. 2 and FIG. 3, a dashed line represents a resonance modality generated when no capacitor and inductor that are connected in series are added to the open slot 11, and a solid line represents a resonance modality generated when a capacitor and an inductor are connected in series in the open slot 11. As shown by dashed lines in FIG. 2 and FIG. 3, a slot antenna generates two operating frequencies that are respectively approximately 2.45 GHz and 5.5 GHz. As shown by solid lines in FIG. 2 and FIG. 3, after the capacitor and the inductor are connected in series in the open slot 11, a new operating frequency of approximately 1.575 GHz is generated.

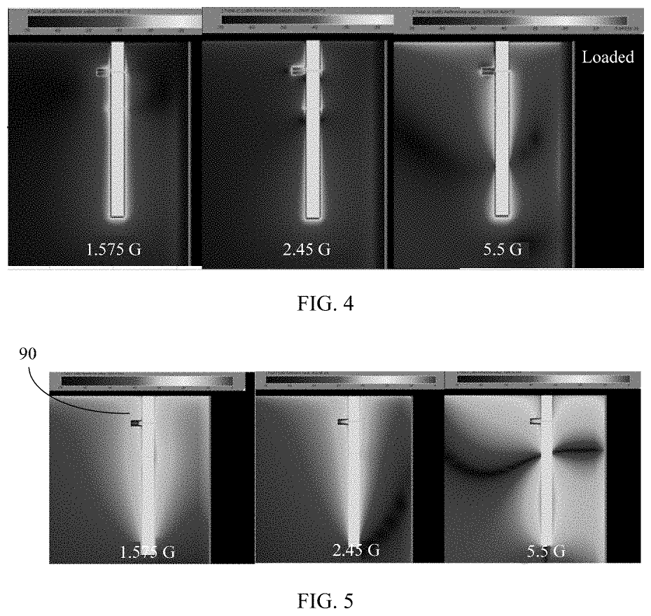

Referring to FIG. 4, FIG. 4 is a schematic diagram of current distribution when a capacitor and an inductor that are connected in series are added to an open slot according to Embodiment 1 of an antenna of the present invention. It may be learned from FIG. 4 that an operating frequency of 1.575 GHz is generated after the capacitor and the inductor are connected in series in the open slot 11, and the current distribution is more even than current distribution corresponding to 2.45 GHz and 5.5 GHz. As shown in FIG. 4, in this embodiment of the antenna of the present invention, a generated current corresponding to 1.575 GHz continues to flow to an edge of the slot.

Referring to FIG. 5, FIG. 5 is a schematic diagram of electric field distribution when a capacitor and an inductor that are connected in series are added to an open slot according to Embodiment 1 of an antenna of the present invention. It may be learned from FIG. 5 that three frequencies that are 1.575 GHz, 2.45 GHz, and 5.5 GHz have equivalent electric field distribution at a feedpoint 90 (it may be understood that the three frequencies that are 1.575 GHz, 2.45 GHz, and 5.5 GHz have high electric fields at the feedpoint). Therefore, resonance of the three frequencies may be excited in a same excitation manner.

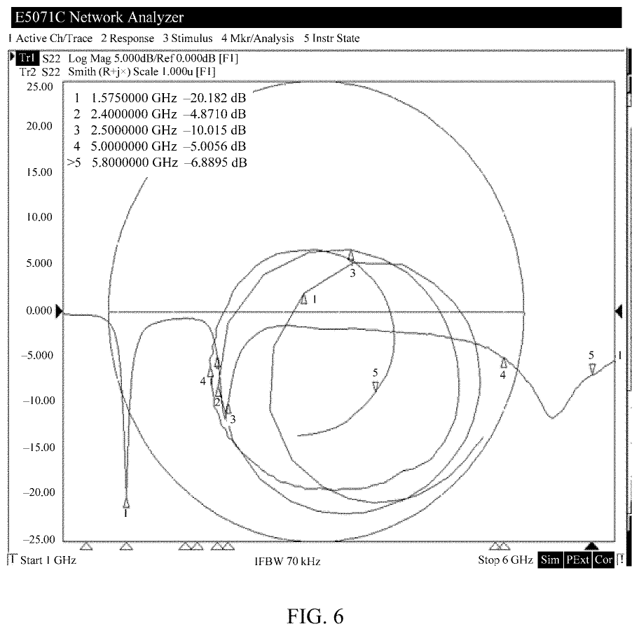

Referring to FIG. 6, FIG. 6 is a diagram of an antenna curve when a capacitor and an inductor that are connected in series are added to an open slot according to Embodiment 1 of an antenna of the present invention. It may be learned from FIG. 6 that, in this embodiment of the antenna of the present invention, an operating frequency of 1.575 GHz may be generated after the capacitor C1 20 and the inductor L1 40 that are connected in series are added to the open slot 11, that is, an operating frequency shown at an approximate location of 1 in FIG. 6.

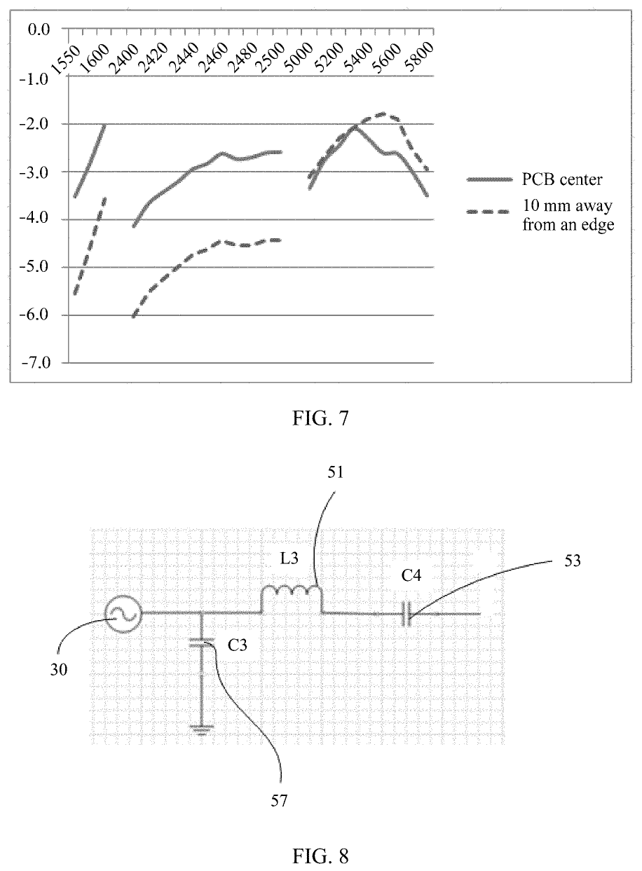

Referring to FIG. 7, FIG. 7 is a schematic diagram of passive efficiency when an open slot is located at different locations on a PCB board according to Embodiment 1 of an antenna of the present invention. As shown in FIG. 7, solid lines show passive efficiency when the open slot 11 is located at an approximately center location on the PCB board, and dashed lines show passive efficiency when the open slot 11 is at a location that is 10 mm away from an edge of the PCB board. It may be learned from FIG. 7 that the open slot 11 is better located at the approximately center location on the PCB board.

### Embodiment 2

Referring to FIG. 1, FIG. 1 is a schematic diagram of an embodiment of an antenna according to the present invention. The antenna 100 includes a printed circuit board (English: Printed Circuit Board, PCB for short), a matching circuit 50, and a feeder 70. The PCB board is provided with a ground plane 10. The ground plane 10 is provided with an open slot 11. One end of the matching circuit 50 is connected to a signal source 30, and the other end of the matching circuit 50 is connected to an end 72 of the feeder 70. The feeder 70 passes across the open slot 11. An endpoint 71 of the feeder 70 is connected to one side 113 of the open slot 11. The antenna 100 further includes a capacitor C1 20 and an inductor L1 40. The capacitor C1 20 and the inductor L1 40 are located in the open slot 11. The capacitor C1 20 and the inductor L1 40 are connected in series. One end of the capacitor C1 20 and the inductor L1 40 that are connected in series is connected to the other side 111 of the open slot 11. The other end of the capacitor C1 20 and the inductor L1 40 that are connected in series is connected to the one side 113 of the open slot 11.

The other side 111 of the open slot 11 is opposite to the one side 113 of the open slot 11.

A size of the PCB board is 135 mm×65 mm×1.6 mm. That is, a length of the PCB board is 135 mm, a width of the PCB board is 65 mm, and a height of the PCB board is 1.6 mm. A distance between the open slot 11 and an edge of the PCB board is greater than or equal to 30 mm.

Optionally or further, a width of the feeder is 0.2 mm.

Optionally or further, a distance between the feeder 70 and an opening of the open slot 11 may be 4 mm.

Optionally or further, a size of the open slot 11 is 10 mm×2 mm. That is, a length of the open slot 11 is 10 mm, and a width of the open slot 11 is 2 mm.

Optionally or further, a value range of a capacitance value of the capacitor C1 20 is 0.5 pF-1 pF, and a value range of an inductance value of the inductor L1 40 is 5 nH-15 nH.

Specifically, the capacitance value of the capacitor C1 20 is 0.5 pF, and the inductance value of the inductor L1 40 is 10 nH.

Still further, the at least two operating frequencies may be 5.5 GHz and 2.45 GHz.

Referring to FIG. 8, the matching circuit 50 includes an inductor L3 51, a capacitor L3 57, and a capacitor C4 53. That one end of the matching circuit 50 is connected to a signal source 30, and the other end of the matching circuit 50 is connected to an end 72 of the feeder 70 includes: One end of the capacitor C3 57 and one end of the inductor L3 51 are connected to the signal source 30, the one end of the capacitor C3 57 is connected to the one end of the inductor L3 51, the other end of the capacitor C3 57 is grounded, the other end of the inductor L3 51 is connected to one end of the capacitor C4 53, and the other end of the capacitor C4 53 is connected to the end 72 of the feeder 70. That the other end of the capacitor C3 57 is grounded may be: The other end of the capacitor C3 57 is connected to the ground plane 10.

The capacitor C4 53 may be configured to tune a low frequency band, and the inductor L3 51 and the capacitor C3 57 may be configured to tune a high frequency band. A capacitance value of the capacitor C4 53 may be 0.5 pF.

As shown in FIG. 1, a location at which the other end of the capacitor C1 20 and the inductor L1 40 that are connected in series is connected to the one side 113 of the open slot 11 is different from a location at which the endpoint 71 of the feeder 70 is connected to the one side 113 of the open slot 11.

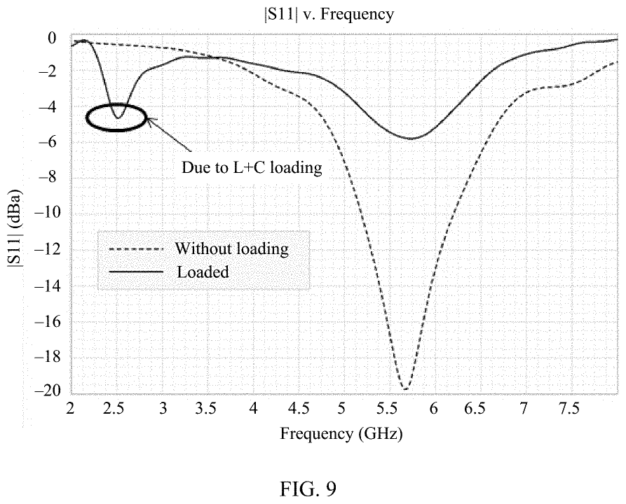

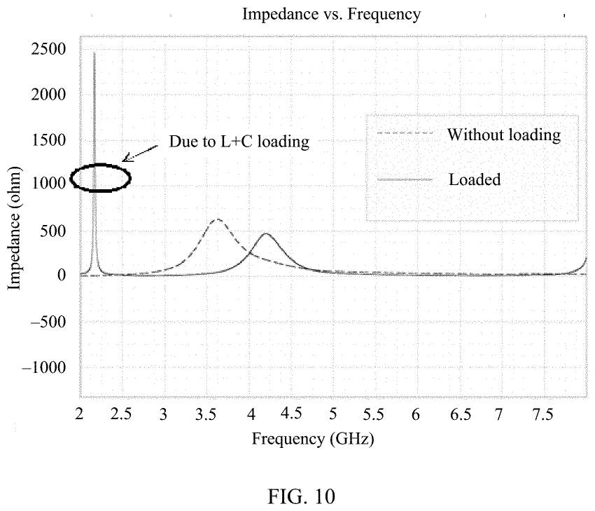

Referring to FIG. 9, FIG. 9 is a schematic diagram of an antenna return loss curve when a capacitor and an inductor that are connected in series are added to an open slot and an antenna return loss curve when no capacitor and inductor that are connected in series are added to an open slot according to Embodiment 2 of an antenna of the present invention. Referring to FIG. 10, FIG. 10 is a schematic diagram of a curve of a real part of impedance when a capacitor and an inductor that are connected in series are added to an open slot and a curve of a real part of impedance when no capacitor and inductor that are connected in series are added to an open slot according to Embodiment 2 of an antenna of the present invention.

As shown in FIG. 9 and FIG. 10, a dashed line represents a resonance modality generated when no capacitor and inductor that are connected in series are added to the open slot 11, and a solid line represents a resonance modality generated when a capacitor and an inductor are connected in series in the open slot 11. As shown by dashed lines in FIG. 9 and FIG. 10, a slot antenna generates an operating frequency of approximately 5.5 GHz. As shown by solid lines in FIG. 9 and FIG. 10, after the capacitor and the inductor are connected in series in the open slot 11, a new operating frequency of approximately 2.45 GHz is generated.

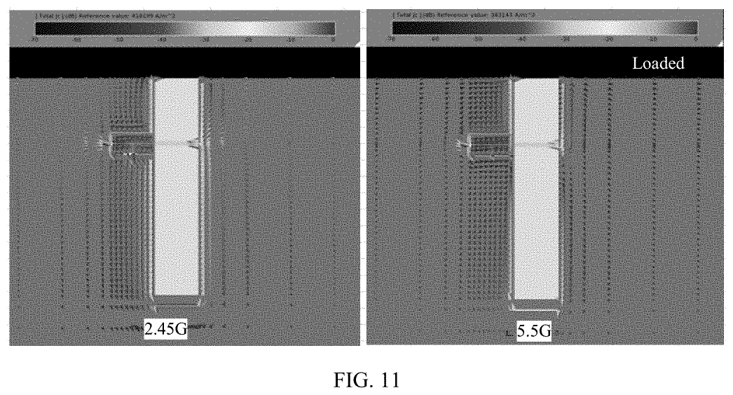

Referring to FIG. 11, FIG. 11 is a schematic diagram of current distribution when a capacitor and an inductor that are connected in series are added to an open slot according to Embodiment 2 of an antenna of the present invention. In this embodiment of the antenna of the present invention, current distribution corresponding to 2.45 GHz is similar to current distribution corresponding to 5.5 GHz.

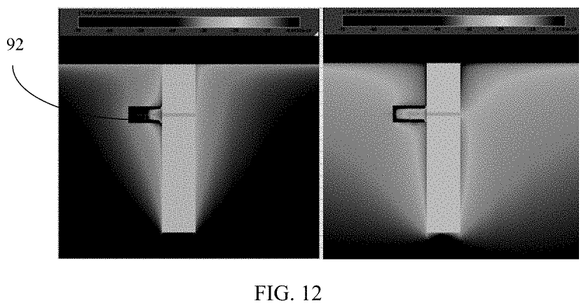

Referring to FIG. 12, FIG. 12 is a schematic diagram of electric field distribution when a capacitor and an inductor that are connected in series are added to an open slot according to Embodiment 2 of an antenna of the present invention. It may be learned from FIG. 12 that two frequencies that are 2.45 GHz and 5.5 GHz have equivalent electric field distribution at a feedpoint 92 (it may be understood that the two frequencies that are 2.45 GHz and 5.5 GHz are high electric fields at the feedpoint). Therefore, resonance of the two frequencies may be excited in a same excitation manner.

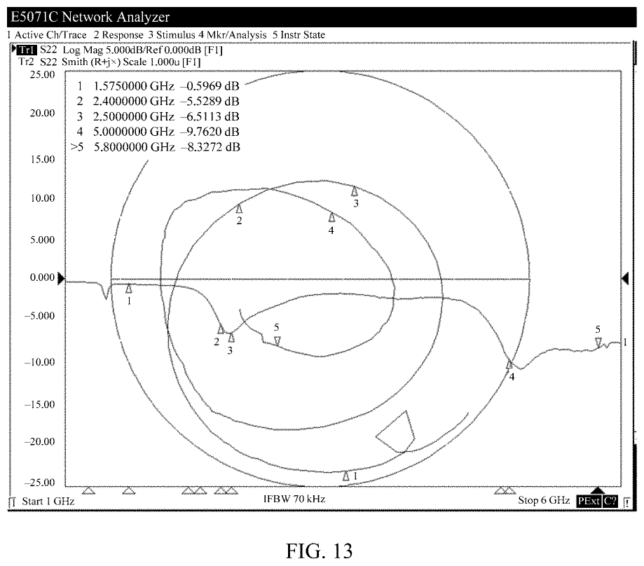

Referring to FIG. 13, FIG. 13 is a diagram of an antenna curve when a capacitor and an inductor that are connected in series are added to an open slot according to Embodiment 2 of an antenna of the present invention. It may be learned from FIG. 13 that, in this embodiment of the antenna of the present invention, after the capacitor C1 20 and the inductor L1 40 that are connected in series are added to the open slot 11, an operating frequency of approximately 2.45 GHz may be generated.

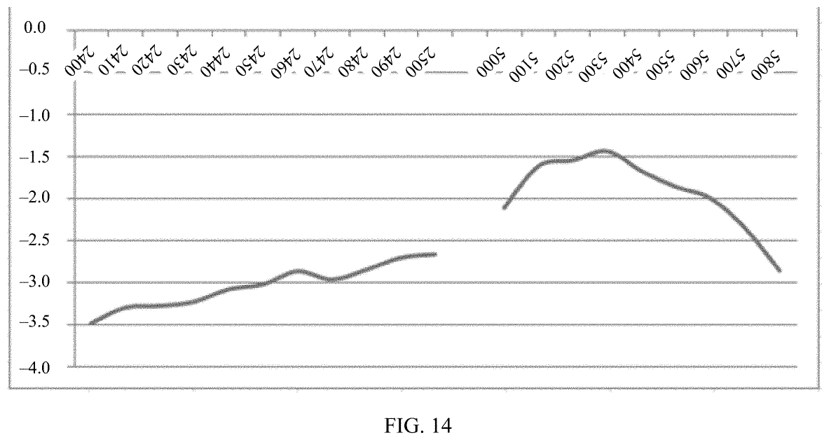

Referring to FIG. 14, FIG. 14 is a schematic diagram of passive efficiency when a capacitor and an inductor that are connected in series are added to an open slot according to an embodiment of an antenna of the present invention. As shown in FIG. 14, in this solution, passive efficiency may reach at least −3.5 dB at a WLAN frequency band (2.4-2.5 G, 5-5.8 G).

### Embodiment 3

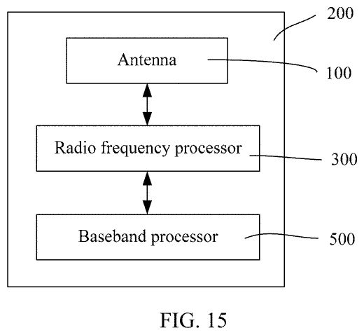

Referring to FIG. 15, FIG. 15 is a schematic diagram of an embodiment of an electronic device according to the present invention. The electronic device 200 includes an antenna 100, a radio frequency processor 300, and a baseband processor 500.

Still referring to FIG. 1, the antenna 100 includes a PCB board, a matching circuit 50, and a feeder 70. The PCB board is provided with a ground plane 10. The ground plane 10 is provided with an open slot 11. One end of the matching circuit 50 is connected to a signal source 30, and the other end of the matching circuit 50 is connected to an end 72 of the feeder 70. The feeder 70 passes across the open slot 11. An endpoint of the feeder 70 is connected to one side of the open slot 11. The antenna further includes a capacitor C1 20 and an inductor L1 40. The capacitor C1 20 and the inductor L1 40 are located in the open slot 11. The capacitor C1 20 and the inductor L1 40 are connected in series. One end of the capacitor C1 20 and the inductor L1 40 that are connected in series is connected to the other side 111 of the open slot 11. The other end of the capacitor C1 20 and the inductor L1 40 that are connected in series is connected to the one side 113 of the open slot 11.

The baseband processor 500 is connected to the signal source 30 by using the radio frequency processor 300.

The antenna 100 is configured to: transmit a received radio signal to the radio frequency processor 300, or convert a transmit signal of the radio frequency processor 300 into an electromagnetic wave and send the electromagnetic wave. The radio frequency processor 300 is configured to: perform frequency selection, amplification, and down-conversion processing on the radio signal received by the antenna 100, convert a processed signal into an intermediate frequency signal or a baseband signal, and send the intermediate frequency signal or the baseband signal to the baseband processor 500; or perform up-conversion and amplification on a baseband signal or an intermediate frequency signal sent by the baseband processor 500, and send a processed signal by using the antenna 100. The baseband processor 500 processes the received intermediate frequency signal or the received baseband signal.

It may be learned from the above that the capacitor C1 20 and the inductor L1 40 that are connected in series are located in the open slot 11, the capacitor C1 20 and the inductor L1 40 that are connected in series are connected to two sides of the open slot 11, and the antenna 100 may further cover a low frequency band based on an original frequency band. In addition, the antenna 100 uses space of the open slot 11, and the capacitor C1 20 and the inductor L1 40 that are connected in series are added to the open slot 11, so as to add the low frequency band without affecting a size of the antenna. Further, the antenna 100 is used on the electronic device 200, so that impact of a surrounding metal component on antenna performance can be reduced.

The other side 111 of the open slot 11 is opposite to the one side 113 of the open slot 11.

For a description of the antenna 100, refer to the description in the antenna embodiment in Embodiment 1 or Embodiment 2. Details are not described herein again.

The electronic device may be a mobile phone, an in-vehicle product (for example, an in-vehicle box T-Box), a tablet computer, a wearable device, or the like. This is not limited in this embodiment of the present invention.

It should be noted that, referring to FIG. 1, the operating frequency provided in the foregoing Embodiment 1 to Embodiment 3 is related to a physical length L of the open slot 11, a matching circuit, and a medium material. A person of ordinary skill in the art may adjust values of an inductor and a capacitor in the matching circuit, and/or select different medium materials, and/or adjust the physical length L of the open slot 11, so as to generate an operating frequency similar to that in Embodiment 1 to Embodiment 3.

In addition, in the antenna embodiments of the present invention, two different matching circuits are provided. A person of ordinary skill in the art may add, based on the two different matching circuits provided in the antenna embodiments of the present invention, a matching circuit with a different capacitor and/or inductor design, or may adjust a value of a capacitor and/or an inductor that are/is of the matching circuit to implement different matching. The matching circuit is not limited in the embodiments of the present invention.

It should be noted that in the antenna embodiments and the electronic device embodiment of the present invention, the capacitor C1 20 and the inductor L1 40 are located in the open slot 11, the capacitor C1 20 and the inductor L1 40 are connected in series, the one end of the capacitor C1 20 and the inductor L1 40 that are connected in series is connected to the other side 111 of the open slot 11, and the other end of the capacitor C1 20 and the inductor L1 40 that are connected in series is connected to the one side 113 of the open slot 11; and based on this, a person of ordinary skill in the art may adjust the capacitance value of the capacitor C1 20 and/or the inductance value of the inductor L1 40 and/or a location that is in the open slot 11 and at which the capacitor C1 20 and the inductor L1 40 that are connected in series are located, so as to adjust the low frequency. In the antenna embodiments and the electronic device embodiment of the present invention, an operating frequency is not limited to the operating frequency of 1.575 GHz generated in Embodiment 1 and the operating frequency of 2.45 GHz generated in Embodiment 2. The capacitance value of the capacitor C1 20 and/or the inductance value of the inductor L1 40 and/or the location that is in the open slot 11 and at which the capacitor C1 20 and inductor L1 40 that are connected in series are located may be adjusted to generate different operating frequencies.

It should be noted that 1.575 GHz, 2.45 GHz, and 5.5 GHz mentioned in the embodiments of the present invention may also be understood as resonance frequencies. For a person of ordinary skill in the art, 7%-13% of a resonance frequency may be a normal operating frequency band (or may be understood as a frequency band) of an antenna. For example, the resonance frequency of the antenna is 5.5 GHz, the normal operating frequency band is 7% of the resonance frequency, and a range of an operating frequency of the antenna may be approximately 5.30 GHz-5.69 GHz.

It should be noted that the ground plane 10 mentioned in the embodiments of the present invention may be a copper plane of the PCB board.

It should be noted that the capacitor and the inductor mentioned in the foregoing Embodiment 1 to Embodiment 3 may be a lumped capacitor and a lumped inductor, or may be a capacitor and an inductor, or certainly may be a distributed capacitor and a distributed inductor. This is not limited in the embodiments of the present invention.

The foregoing descriptions are merely example embodiments of the present invention, but are not intended to limit the present invention. Any modification, equivalent replacement, and improvement made without departing from the principle of the present invention shall fall within the protection scope of the present invention.

1. An antenna, wherein the antenna comprises:
a PCB board;
a matching circuit; and
a feeder;
a capacitor C1; and
an inductor L1
wherein:
the PCB board is provided with a ground plane,
the ground plane is provided with an open slot,
one end of the matching circuit is connected to a signal source, the other end of the matching circuit is connected to an end of the feeder,
the feeder passes across the open slot, and an endpoint of the feeder is connected to one side of the open slot,
the capacitor C1 and the inductor L1 are located in the open slot,
the capacitor C1 and the inductor L1 are connected in series, and
one end of the capacitor C1 and the inductor L1 that are connected in series is connected to the other side of the open slot, and the other end of the capacitor C1 and the inductor L1 that are connected in series is connected to the one side of the open slot.

2. The antenna according to claim 1, wherein a size of the open slot is 25 mm×2 mm.

3. The antenna according to claim 1, wherein a value range of a capacitance value of the capacitor C1 is 0.5 pF-1 pF, and a value range of an inductance value of the inductor L1 is 5 nH-15 nH.

4. The antenna according to claim 3, wherein the capacitance value of the capacitor C1 is 0.5 pF, and the inductance value of the inductor L1 is 9.1 nH.

5. The antenna according to claim 4, wherein the antenna generates at least three operating frequencies.

6. The antenna according to claim 5, wherein the at least three operating frequencies comprise 2.45 GHz, 5.5 GHz, and 1.575 GHz.

7. The antenna according to claim 1, wherein a size of the PCB board is 135 mm×65 mm×1.6 mm, and a distance between the open slot and an edge of the PCB board is greater than or equal to 30 mm.

8. The antenna according to claim 1, wherein the size of the open slot is 10 mm×2 mm.

9. The antenna according to claim 8, wherein a capacitance value of the capacitor C1 is 0.5 pF, and an inductance value of the inductor L1 is 10 nH.

10. The antenna according to claim 9, wherein the antenna generates at least two operating frequencies.

11. The antenna according to claim 10, wherein the at least two operating frequencies comprise 5.5 GHz and 2.45 GHz.

12. The antenna according to claim 11, wherein a width of the feeder is 0.2 mm.

13. An electronic device, comprising:
an antenna,
a radio frequency processor, and
a baseband processor,
wherein the antenna comprises a PCB board, a matching circuit, a feeder, a capacitor C1 and an inductor L1, wherein the PCB board is provided with a ground plane, the ground plane is provided with an open slot, one end of the matching circuit is connected to a signal source, the other end of the matching circuit is connected to an end of the feeder, the feeder passes across the open slot, and an endpoint of the feeder is connected to one side of the open slot; the capacitor C1 and the inductor L1 are located in the open slot, the capacitor C1 and the inductor L1 are connected in series, one end of the capacitor C1 and the inductor L1 that are connected in series is connected to the other side of the open slot, and the other end of the capacitor C1 and the inductor L1 that are connected in series is connected to the one side of the open slot;
the baseband processor is connected to the signal source by the radio frequency processor; and
the antenna is configured to: transmit a received radio signal to the radio frequency processor, or convert a transmit signal of the radio frequency processor into an electromagnetic wave and send the electromagnetic wave;
the radio frequency processor is configured to:
perform frequency selection, amplification, and down-conversion processing on the radio signal received by the antenna,
convert a processed signal into an intermediate frequency signal or a baseband signal, and
send the intermediate frequency signal or the baseband signal to the baseband processor; or
perform up-conversion and amplification on a baseband signal or an intermediate frequency signal sent by the baseband processor, and
send a processed signal by the antenna; and
the baseband processor processes the received intermediate frequency signal or the received baseband signal.

14. The electronic device according to claim 13, wherein a size of the open slot is 25 mm×2 mm.

15. The electronic device according to claim 13, wherein a value range of a capacitance value of the capacitor C1 is 0.5 pF-1 pF, and a value range of an inductance value of the inductor L1 is 5 nH-15 nH.

16. The electronic device according to claim 15, wherein the capacitance value of the capacitor C1 is 0.5 pF, and the inductance value of the inductor L1 is 9.1 nH.

17. The electronic device according to claim 16, wherein the antenna generates at least three operating frequencies.

18. The electronic device according to claim 17, wherein the at least three operating frequencies comprise 2.45 GHz, 5.5 GHz, and 1.575 GHz.

19. The electronic device according to claim 13, wherein a size of the PCB board is 135 mm×65 mm×1.6 mm, and a distance between the open slot and an edge of the PCB board is greater than or equal to 30 mm.

20. The electronic device according to claim 13, wherein the size of the open slot is 10 mm×2 mm.

21. The electronic device according to claim 20, wherein a capacitance value of the capacitor C1 is 0.5 pF, and an inductance value of the inductor L1 is 10 nH.

22. The electronic device according to claim 21, wherein the antenna generates at least two operating frequencies.

23. The electronic device according to claim 22, wherein the at least two operating frequencies comprise 5.5 GHz and 2.45 GHz.

24. The electronic device according to claim 23, wherein a width of the feeder is 0.2 mm.

25. (canceled)
